(19) United States
(12) Patent Application Publication
(10) Pub. No.: US 2015/0076651 A1
(43) Pub. Date: Mar. 19, 2015

(54) THERMOCOUPLE, THERMOPILE, INFRARED RAY SENSOR AND METHOD OF MANUFACTURING INFRARED RAY SENSOR

(71) Applicant: Hidetaka Noguchi, Hyogo (JP)

(72) Inventor: Hidetaka Noguchi, Hyogo (JP)

(73) Assignee: RICOH COMPANY, LTD., Tokyo (JP)

(21) Appl. No.: 14/206,087

(22) Filed: Mar. 12, 2014

(30) Foreign Application Priority Data
Sep. 18, 2013 (JP) 2013-192685

(51) Int. Cl. H01L 35/32; H01L 35/34; G01J 5/12

(52) U.S. Cl. CPC H01L 35/32; G01J 5/12; H01L 35/34
USPC 257/467; 438/54

(57) ABSTRACT

An infrared ray sensor includes a thermopile. The thermopile includes a first semiconductor material part and a second semiconductor material part, the first semiconductor material part and the second semiconductor material part are laminated, and a dielectric film is provided between the first semiconductor material part and the second semiconductor material part.

### BACKGROUND OF THE INVENTION

1. Field of the Invention

The present invention relates to a thermocouple, a thermopile, an infrared ray sensor and a method of manufacturing an infrared ray sensor.

2. Description of the Related Art

Recently, development of bolometers, thermopiles, non-cooling thermal infrared ray array sensors using diodes and/or the like, thermal infrared ray line sensors and so forth is being carried out actively. These sensors have sensitivities for wavelength bands from mid infrared bands to far infrared bands and therefore are widely used for night vision cameras for automobiles, human body sensors for security equipment, human body sensors for energy saving of electric/electronic equipment and so forth.

In particular, thermopile type sensors do not require driving power sources and are capable of easily realizing low power consumption. Also, it is possible to produce them by materials such as polysilicon or aluminum used in a usual Complementary Metal Oxide Semiconductor (CMOS) process. Therefore, it is easy to realize a monolithic configuration including peripheral circuits. From these viewpoints, development of relatively small-scale infrared ray array sensors using thermopiles is being carried out actively.

Further, as materials of thermopiles, it is known to use a pair of n-type polysilicon and p-type polysilicon having mutually different polarities of Seebeck coefficients (for example, see Japanese Laid-Open Patent Application No. 2000-307159 (Patent Reference No. 1)). In a thermopile using n-type polysilicon and p-type polysilicon, n-type polysilicon and p-type polysilicon are placed alternately across hot junctions and cold junctions, and all of the n-type polysilicon and the p-type polysilicon are connected in series using conductive material.

Further, in these infrared ray sensors, in order to obtain sufficient sensitivities for weak infrared rays, hot junctions in a thermopile are usually formed on a heat insulating structure such as a bridge structure or a diaphragm structure formed by a MEMS process.

### SUMMARY OF THE INVENTION

According to one aspect of the present invention, n infrared ray sensor includes a thermopile. The thermopile includes a first semiconductor material part and a second semiconductor material part, the first semiconductor material part and the second semiconductor material part are laminated, and a dielectric film is provided between the first semiconductor material part and the second semiconductor material part.

Other objects, features and advantages of the present invention will become more apparent from the following detailed description when read in conjunction with the accompanying drawings.

### BRIEF DESCRIPTION OF THE DRAWINGS

FIGS. 1A and 1B are schematic views illustrating an embodiment, FIG. 1A being a plan view and FIG. 1B being a sectional view taken along a A-A′ line of FIG. 1A;

FIG. 2 is a schematic sectional view illustrating another embodiment;

FIGS. 3A and 3B are schematic views illustrating further another embodiment, FIG. 3A being a plan view and FIG. 3B being a sectional view taken along a B-B′ line of FIG. 3A;

FIGS. 4A and 4B are schematic views illustrating yet another embodiment, FIG. 4A being a plan view and FIG. 4B being a sectional view taken along a C-C′ line of FIG. 4A;

FIG. 5 is a schematic sectional view showing a connection part between semiconductor material parts in the embodiment of FIGS. 4A and 4B in a magnified manner;

FIGS. 6A and 6B are schematic views illustrating yet another embodiment, FIG. 6A being a plan view and FIG. 6B being a sectional view taken along a D-D′ line of FIG. 6A in a magnified manner;

FIG. 7 is a schematic sectional view showing a connection part between semiconductor material parts in the embodiment of FIGS. 6A and 6B; FIGS. 8A, 8B, 8C, 8D and BE are sectional views illustrating an example of processes of manufacturing a thermopile according to the embodiment of FIGS. 6A and 6B;

FIG. 9 is a schematic sectional view illustrating yet another embodiment;

FIG. 10 is a schematic plan view illustrating yet another embodiment;

FIGS. 11A and 11B are schematic views illustrating the related art, FIG. 11A being a plan view and FIG. 11B being a sectional view taken along a X-X′ line of FIG. 11A;

FIGS. 12A and 12B are schematic views illustrating connection parts between thermopile material parts and a conductive material part in an infrared ray sensor in the related art, FIG. 12A being a plan view and FIG. 12B being a sectional view taken along a Y-Y′ line of FIG. 12A;

FIGS. 13A, 13B and 13C are schematic views illustrating yet another embodiment, FIG. 13A being a plan view, FIG. 13B being a sectional view taken along a E-E′ line of FIG. 13A and FIG. 13C being a sectional view taken along a F-F′ line of FIG. 13A;

FIG. 14 is a schematic view showing a part enclosed by an alternating long and short dashed line in FIG. 13B in a magnified manner;

FIG. 15 is a schematic view showing a part enclosed by an alternating long and short dashed line in FIG. 13C in a magnified manner;

FIGS. 16A, 16B, 16C, 16D, 16E, 16F and 16G are schematic sectional views illustrating one example of processes of manufacturing a thermopile according to the embodiment of FIGS. 13A, 13B and 13C;

FIG. 17A is a schematic plan view corresponding to the schematic sectional view of FIG. 16B;

FIG. 17B is a schematic plan view corresponding to the schematic sectional view of FIG. 16D;

FIG. 17C is a schematic plan view corresponding to the schematic sectional view of FIG. 16E;

FIG. 17D is a schematic plan view corresponding to the schematic sectional view of FIG. 16G; and

FIG. 18 is a schematic sectional view illustrating yet another embodiment.

### DETAILED DESCRIPTION OF THE EMBODIMENTS

Below, using the drawings, the embodiments of the present invention will be described in detail.

Generally speaking, in an infrared ray sensor of a thermopile type, the sensitivity of the sensor is in proportion to the number of pairs (the number of thermocouples) in a thermopile. Therefore, the sensitivity increases as the number of pairs in the thermopile is increased. However, as the number of pairs in the thermopile is creased, the size of the sensor increases, the heat capacity increase accordingly and as a result, the response characteristics may be degraded.

The embodiments of the present invention have been devised for the purpose of increasing the number of pairs in the thermopile per unit area.

In the above-mentioned infrared ray sensor according to the aspect of the present invention, the dielectric film can be, for example, a thermal oxide film of the first semiconductor material part. In yet example, another dielectric film can be laminated on the thermal oxide film between the first semiconductor material part and the second semiconductor material part. A specific material of the other dielectric film is not particularly limited.

In the above-mentioned infrared ray sensor according to the aspect of the present invention, in yet another example, the first semiconductor material part and the second semiconductor material part can have impurities introduced thereinto with concentrations that are different between the first semiconductor material part and the second semiconductor material part, the impurities generating carriers with polarities that are the same between the first semiconductor material part and the second semiconductor material part, and the first semiconductor material part and the second semiconductor material part have Seebeck coefficients with polarities that are reversed between the first semiconductor material part and the second semiconductor material part. However, the first semiconductor material part and the second semiconductor material part are not limited thereto in an embodiment of the present invention.

In the above-mentioned infrared ray sensor according to the aspect of the present invention, in yet another example, the concentrations of the impurities introduced into the first semiconductor material part and the second semiconductor material part can be selected or adjusted in such a manner that the polarities of the Seebeck coefficients are reversed between the first semiconductor material part and the second semiconductor material part. However, the first semiconductor material part and the second semiconductor material part are not limited thereto in an embodiment of the present invention.

In the above-mentioned infrared ray sensor according to the aspect of the present invention, in yet another example, the first semiconductor material part and the second semiconductor material part can be made of semiconductor materials that chiefly include silicon. However, the first semiconductor material part and the second semiconductor material part can be made of semiconductor materials that chiefly include a semiconductor other than silicon.

In the above-mentioned infrared ray sensor according to the aspect of the present invention, in yet another example, the impurities introduced into the first semiconductor material part and the second semiconductor material part can be n-type impurities. However, the impurities can be p-type impurities.

In the above-mentioned infrared ray sensor according to the aspect of the present invention, in yet another example, in either the first semiconductor material part or the second semiconductor material part, the concentration of the impurity reaches a solid-solubility limit. However, in the first semiconductor material part and the second semiconductor material part, the concentrations of the impurities can be those that do not reach solid-solubility limits.

In the above-mentioned infrared ray sensor according to the aspect of the present invention, in yet another example, side faces of the first semiconductor material part and the second semiconductor material part lying along longitudinal directions of the first semiconductor material part and the second semiconductor material part can lie on a same plane. However, the side faces of the first semiconductor material part and the second semiconductor material part lying along longitudinal directions of the first semiconductor material part and the second semiconductor material part can also lie on different planes.

A method of manufacturing the infrared ray sensor according to the aspect of the present invention includes etching the first semiconductor material part and the second semiconductor material part simultaneously. However, the infrared ray sensor according to the aspect of the present invention can be manufactured also in a method that does not include etching the first semiconductor material part and the second semiconductor material part simultaneously.

Next, an infrared ray sensor in the related art will be described.

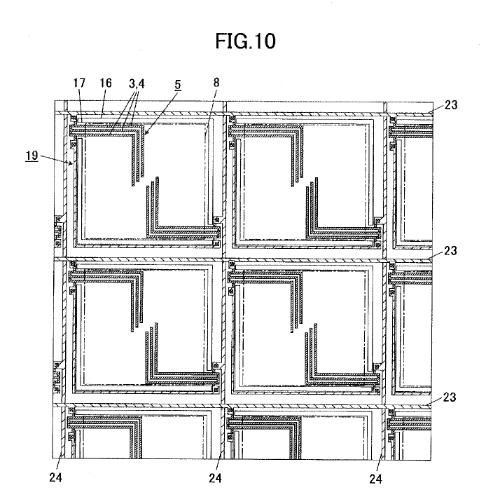

FIGS. 11A and 11B are schematic views illustrating the related art, FIG. 11A is a plan view and FIG. 11B is a sectional view taken along an X-X′ line of FIG. 11A.

On a substrate 101, thermocouples are formed by first thermocouple material parts 103 and second thermocouple material parts 104 included in a thermopile 102 connected by conductive material parts 105. A plurality of the thermocouples are connected in series by the conductive material parts 105 to form the thermopile 102.

As materials of the first thermocouple material parts 103 and the second thermocouple material parts 104, generally speaking, n-type polysilicon and p-type polysilicon having Seebeck coefficients with different polarities are usually used. The first thermocouple material parts 103 and the second thermocouple material parts 104 are connected by the conductive material parts 105 made of aluminum or the like via contact holes 106.

Further, in order to detect weak infrared rays with good sensitivity, a cavity part 107 is formed below the thermopile 102 and a heat insulating structure is provided. The junctions in the thermopile 102 on a thin film part thermally insulated from the substrate 101 by the cavity part 107 act as hot junctions while junctions in the thermopile 102 above the substrate 1 without the cavity part 107 act as cold junctions. Further, an infrared ray absorbing film 108 is formed to cover the hot junctions of the thermopile 102.

The first thermocouple material parts 103 and the second thermocouple material parts 104 are formed on a dielectric film 109 formed on the substrate 101. On the dielectric film 109, an interlayer dielectric film 110 is formed to cover the first thermocouple material parts 103 and the second thermocouple material parts 104. On the interlayer dielectric film 110, the conductive material parts 105 are formed. The contact holes 106 are formed in the interlayer dielectric film 110 between the first and second thermocouple material parts 103 and 104 and the conductive material parts 105. On the interlayer dielectric film 110, another interlayer dielectric film 110 is formed to cover the conductive material parts 105. These interlayer dielectric films 110 (not shown in FIG. 11A) are shown in a manner of being integrated. On the interlayer dielectric films 110, the infrared ray absorbing film 108 is formed.

As the substrate 101, a silicon substrate is generally used since a Micro Electro Mechanical System (MEMS) process of silicon is used for forming the heat insulating structure. As the dielectric film 109, a silicon thermal oxide film is usually used. As the interlayer dielectric films 110, plasma oxide films or Chemical Vapor Deposition (CVD) films of silicon are usually used. As the infrared ray absorbing film 108, a silicon oxide film, a silicon nitride film, a gold black film or the like is used.

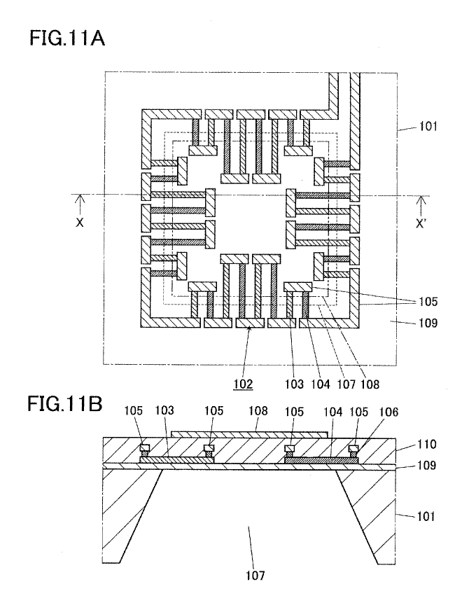

FIGS. 12A and 12B are schematic views illustrating connection parts between thermopile material parts and a conductive material part in an infrared ray sensor in the related art. FIG. 12A is a plan view and FIG. 12B is a sectional view taken along a X-X′ line of FIG. 12A. In FIGS. 12A and 12B, the same reference numerals are given to parts providing the same functions as those shown in FIGS. 11A and 11B.

The first thermocouple material part 103 and the conductive material part 105 are electrically connected through the contact hole 106 formed on a contact part 103a of the first thermocouple material part 103. The second thermocouple material part 104 and the conductive material part 105 are electrically connected through the contact hole 106 formed on a contact part 104a of the second thermocouple material part 104.

At the time, in order to ensure positive electric conduction, the size of the contact holes 106 and overlapping amounts between the contact holes 106 and the respective material parts 103, 104 and 105 are prescribed in a design rule. Therefore, the sizes of the contact parts 103a and 104a are increased with respect to the widths of the thermocouple material parts 103 and 104. Thus, freedom in the layout is restricted.

For example, when the thermopile 102 (see FIGS. 11A and 11B) is laid out within a predetermined area, since the areas of the contact parts 103a and 104a are needed, it may be impossible to arrange the thermopile 102 with a highest density. Therefore, the number of thermocouples in the thermopile 102 may be reduced and the sensitivity may be degraded accordingly.

Further, when laying out the thermopile 102 having a predetermined number of thermocouples, it is necessary to increase the size of the cavity part 107 since the areas of the contact parts 103a and 104a are needed. As a result, the heat capacity of the thin film part may increase and the response speed of the sensor may be degraded.

According to Patent Reference No. 1, layout is devised to minimize the areas of the contact parts 103a and 104a. However, since it may be impossible to completely avoid providing the contact parts 103a and 104a, it may be impossible to solve the problem completely.

Further, electric conduction is achieved by the contact holes 106 at the junctions between the contact part 103a of the first thermocouple material part 103 and the conductive material part 105 and the junctions between the contact part 104a of the second thermocouple material part 104 and the conductive material part 105. Therefore, the thickness of the interlayer dielectric films 110 is increased by the thickness of the contact holes 106 and the conductive material part 105. As the thickness of the interlayer dielectric films 110 is thus increased, the heat capacity of the sensor may increase and the response speed of the sensor may be degraded.

Thus, in such an infrared ray sensor using a thermopile formed by p-type polysilicon and n-type polysilicon in the related art, it is necessary to connect polysilicon material parts by conductive material parts. This is because if p-type polysilicon and n-type polysilicon are directly connected, a depletion layer is formed near the connection surface. Therefore, in an infrared ray sensor in the related art, contact parts are absolutely needed for electric conduction between polysilicon and conductive material.

Therefore, in an infrared ray sensor in the related art, by an influence of such contact parts, the number of thermocouples Sc be formed on a heat insulating structure having a certain area is restricted, or the size of the heat insulating structure is increased for forming a certain number of thermocouples. Therefore, it may be impossible to obtain sufficient sensitivity of a sensor or sufficient response speed in an infrared ray sensor in the related art.

A second objective of the embodiments of the present invention is to avoid providing contact parts using other conductive material parts for electric connection between thermocouple material parts.

A thermocouple according to an embodiment of the present invention includes a first semiconductor material part and a second semiconductor material part that are electrically connected. The first semiconductor material part and the second semiconductor material part are such that impurities that generate carriers having the same polarity are introduced with mutually different concentrations and the polarities of Seebeck coefficients are the reverse of one another.

In the thermocouple, the concentrations of the impurities introduced into the first it semiconductor material part and the second semiconductor material part can be selected or adjusted in such a manner that the polarities of the Seebeck coefficients are reversed between the first semiconductor material part and the second semiconductor material part, as one example. However, the first semiconductor material part and the second semiconductor material part are not limited thereto in an embodiment of the present invention.

In the thermocouple, the first semiconductor material part and the second semiconductor material part can be made of semiconductor materials that chiefly include silicon, as one example. However, the first semiconductor material part and the second semiconductor material part can be made of semiconductor materials that chiefly include a semiconductor other than silicon.

In the thermocouple, the impurities introduced into the first semiconductor material part and the second semiconductor material part can be n-type impurities, as one example. However, the impurities can be p-type impurities.

In the thermocouple, in either one of the first semiconductor material part and the second semiconductor material part, the concentration of the impurity reaches a solid-solubility limit, as one example. However, in the first semiconductor material part and the second semiconductor material part, the concentrations of the impurities can be those that do not reach solid-solubility limits.

In the thermocouple, the first semiconductor material part and the second semiconductor material part can be formed from different layers of semiconductor materials, for example. However, the first semiconductor material part and the second semiconductor material part can be formed by using the same layer of a semiconductor material.

A thermopile according to an embodiment of the present invention includes a plurality of the above-mentioned thermocouples connected in series or parallel with each other.

An infrared ray sensor in a second mode of the present invention includes the thermopile according to the embodiment of the present invention. The thermopile includes the plurality of thermocouples connected in series with each other.

In an infrared ray sensor according to one embodiment of the present invention, the thermopile and a peripheral circuit are formed on the same substrate. However, it is also possible that the thermopile and the peripheral circuit are not formed on the same substrate.

In an infrared ray sensor according to one embodiment of the present invention, a plurality of the thermopiles are arranged to form an array. However, it is also possible that the plurality of the thermopiles are arranged to have an arrangement other than an array. For example, the plurality of thermopiles can be arranged linearly or form a staggered arrangement. Further, in an infrared ray sensor according to one embodiment of the present invention, the number of the thermopiles can be one.

A thermocouple in an embodiment of the present invention includes a first semiconductor material part and a second semiconductor material part. The first semiconductor material part and the second semiconductor material part have impurities introduced thereinto with concentrations that are different between the first semiconductor material part and the second semiconductor material part. The impurities generate carriers with polarities that are the same between the first semiconductor material part and the second semiconductor material part. The first semiconductor material part and the second semiconductor material part have Seebeck coefficients with polarities that are reversed between the first semiconductor material part and the second semiconductor material part. In this configuration, although the first semiconductor material part and the second semiconductor material part are directly connected, no depletion layer is formed between the first semiconductor material part and the second semiconductor material part. Therefore, by the thermocouple according to the embodiment, it is possible to avoid providing contact parts using other conductive material parts for electric connection between the thermocouple material parts.

The thermopile includes the thermocouple according to the embodiment of the present invention. Therefore, since it is possible to avoid providing contact parts using other conductive material parts for electric condition between the thermocouple material parts as mentioned above, in the thermopile, it is possible to reduce the arranging intervals between the thermocouple material parts. Thereby, in the thermopile according to the embodiment, it is possible to reduce the area required for providing the thermopile or increase the number of thermocouples for the same area.

Since the infrared ray sensor in the second mode of the present invention includes the thermopile according to the embodiment of the present invention, it is possible to reduce the area required for providing the thermopile or increase the number of thermocouples for the same area as mentioned above. Accordingly, in the infrared ray sensor in the second mode of the present invention, it is possible to reduce the area of the infrared ray sensor itself or increase the sensitivity of the sensor.

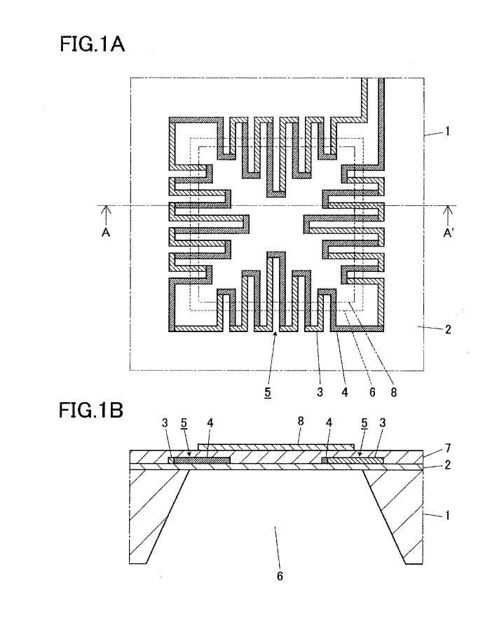

FIGS. 1A and 1B are schematic views illustrating an embodiment. FIG. 1A is a plan view and FIG. 1B is a sectional view taken along an A-A′ line of FIG. 1A.

On a dielectric film 2 formed on a substrate 1, a plurality of first semiconductor material parts 3 and a plurality of second semiconductor material parts 4 are formed to form a plurality of thermocouples. A thermopile 5 is formed as a result of the plurality of semiconductor material parts 3 and 4 are alternately connected in series. The semiconductor material parts 3 and 4 are electrically connected in a manner of being connected directly.

The semiconductor material parts 3 and 4 have impurities introduced thereinto with concentrations that are different between the semiconductor material parts 3 and 4. The impurities generate carriers with polarities that are the same between the semiconductor material parts 3 and 4. Further, the semiconductor material parts 3 and 4 have Seebeck coefficients with polarities that are reversed between the semiconductor material parts 3 and 4. The impurity concentration of the first semiconductor material parts 3 can be higher or lower than the impurity concentration of the second semiconductor material parts 4.

The semiconductor material parts 3 and 4 are formed as a result of the same semiconductor layer being machined. Introduction of the impurities into the semiconductor material parts 3 and 4 can be carried out before or after the machining of the semiconductor layer. Further, impurity can be introduced into areas for forming either of the semiconductor material parts 3 and 4 before machining the semiconductor layer, and then, impurity can be introduced into positions for forming the other of the semiconductor material parts 3 and 4 after machining the semiconductor layer. In this case, in the process of introducing the impurity after machining the semiconductor layer, the impurity can be introduced in addition to the areas where the impurity was introduced before the machining the semiconductor layer. Further, it is also possible to introduce the impurities at a time of forming the semiconductor layer.

In order to detect weak infrared rays with good sensitivity, a cavity part 6 is formed in the substrate 1 below the thermopile 5 and a heat insulating structure is formed. Junctions (where the first semiconductor material parts 3 and the second semiconductor material parts 4 are connected) in the thermopile 5 placed above the dielectric film 2 thermally separated from the substrate 1 by the cavity part 6 function as hot junctions. Junctions in the thermopile 5 above the substrate 1 where the cavity part 6 is absent function as cold junctions.

On the dielectric film 2, interlayer dielectric films 7 (not shown in FIG. 1A) are formed to cover the thermopile 5. On the interlayer dielectric films 7, an infrared absorbing film 8 is formed at a position to cover the hot junctions of the thermopile 5 when viewed from the top.

As shown in FIG. 1B, the infrared ray sensor has a configuration such that the substrate 1, the dielectric film 2, the semiconductor material parts 3 and 4, the interlayer dielectric films 7 and the infrared absorbing film 8 are laminated. As the substrate 1, a silicon substrate is usually used since a MEMS process of silicon is generally used for forming the heat insulating structure.

The dielectric film 2 is a silicon thermal oxide film, for example. The interlayer dielectric films 7 are, for example, plasma oxide films or CVD films of silicon. The infrared ray absorbing film 8 is formed of, for example, a silicon oxide film, a silicon nitride film, a gold black film or the like. However, the materials of these layers are not limited thereto in an embodiment of the present invention.

What is different from the infrared ray sensor shown in FIGS. 11A and 11B in the present embodiment is that connection between the first semiconductor material parts 3 and the second semiconductor material parts 4 are not carried out using conductive material parts other than the semiconductor material parts 3 and 4 but the semiconductor material parts 3 and 4 are directly connected. According to the present embodiment, the semiconductor material parts 3 and 4 have impurities that generate carriers having the same polarity (positive holes or electrons) introduced thereinto, and also, the impurity concentrations are adjusted so that the polarities of Seebeck coefficients of the semiconductor material parts 3 and 4 are the reverse of each other. Therefore, the semiconductor material parts 3 and 4 are made of semiconductor materials that have the same conductivity type.

For example, IEICE Technical Report, ED2009-197, SDM2009-194 (2010-2), pp. 5-9 (Non-patent Reference No. 1) and IEICE Technical Report, ED2010-194, SDM2010-229 (2011-2), pp. 13-17 (Non-patent Reference No. 2) disclose the relation between impurity concentration of phosphorus and Seebeck coefficient of silicon in a thin-film single crystal silicon layer (active layer) in a Silicon on Insulator (SOI) substrate. According to Non-patent References Nos. 1 and 2, the polarity of the Seebeck coefficient of silicon is inverted depending on the impurity concentration of phosphorus.

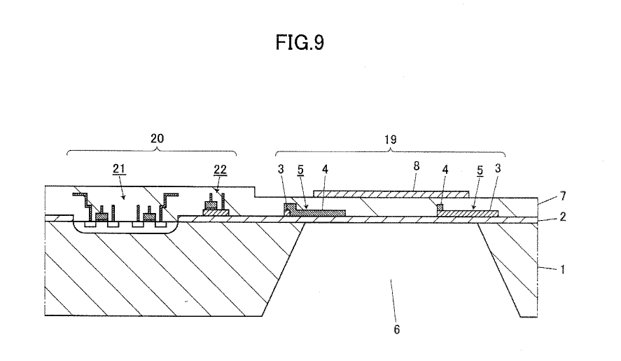

Returning to FIGS. 1A and 10, description of the infrared ray sensor will be continued.

One example of a base material of the semiconductor material parts 3 and 4 is polysilicon. Into the first semiconductor material parts 3, phosphorus is introduced in such a manner that the impurity concentration on the order of 1×10¹⁸ to 1×10¹⁹ cm⁻³ is obtained. Into the second semiconductor material parts 4, phosphorus having the impurity concentration on the order of 5×10²⁰ cm⁻³ which is the solid-solubility limit of phosphorus to silicon is introduced.

As another example, into the first semiconductor material parts 3, boron is introduced in such a manner that the impurity concentration on the order of 1×10¹⁸ to 1×10¹⁹ cm⁻³ is obtained. Into the second semiconductor material parts 4, boron having the impurity concentration on the order of 1×10²⁰ cm⁻³ which is the solid-solubility limit of boron to silicon is introduced. A basic material of the semiconductor material parts 3 and is polysilicon.

Note that a semiconductor material into which n-type impurity is introduced, for example, n-type polysilicon, has a resistance value lower than a semiconductor material into which p-type impurity is introduced, for example, p-type polysilicon. Therefore, by using, as the thermopile 5, semiconductor material parts 3 and 4 into which n-type impurity is introduced, it is possible to improve the S/N ratio of the sensor.

As a specific method of introducing impurity, impurity is to be introduced into the semiconductor material parts 3 and 4 with appropriate concentrations by using a method such as ion implantation, surface diffusion or the like. For the semiconductor material parts 3 or the semiconductor material parts 4, which have the higher impurity concentration, it is not necessary to introduce the impurity to the solid-solubility limit. Note that when using the semiconductor material parts 3 and 4 of n-type, both phosphorus and arsenic that are n-type impurities can be introduced.

Note that the materials, the types of impurities and the impurity concentrations of the semiconductor material parts 3 and 4 mentioned above are examples. What is necessary is that the semiconductor material parts 3 and 4 have impurities that generate carriers having the same conductivity type, and also, the impurity connections are adjusted so that the polarities of Seebeck coefficients of the semiconductor material parts 3 and 4 are the reverse of one another. The materials, the types of impurities and the impurity concentrations of the semiconductor material parts 3 and 4 are not limited to the embodiment in an embodiment of the present invention. Basic semiconductor materials of the semiconductor material parts 3 and 4 can be different from one another.

Note that in the infrared ray sensor in the related art in which the thermocouples using p-type polysilicon and n-type polysilicon are used as the thermopile, it is assumed that p-type polysilicon and n-type polysilicon are directly connected. In this case, a depletion layer is formed at a connection part between p-type polysilicon and n-type polysilicon. Therefore, in the infrared ray sensor in the related art, other conductive material parts are necessarily used to connect p-type polysilicon and n-type polysilicon so as to obtain ohmic contact therebetween (see FIGS. 11A and 11B).

In contrast thereto, according to the embodiment shown in FIGS. 1A and 1B, the semiconductor material parts 3 and 4 included in the thermopile 5 are made of semiconductor materials having the same conductivity type. Therefore, when the semiconductor material parts 3 and 4 are directly connected, no depletion layer is generated, and therefore, it is not necessary to use other conductive material parts for connection between the semiconductor material parts 3 and 4.

Thus, according to the present embodiment, other conductive material parts and contact parts required together for connecting the semiconductor material parts 3 and 4 are not needed. As a result, the layout restriction is eased. Accordingly, according to the present embodiment, in comparison to the infrared ray sensor in the related art of FIGS. 11A and 11B, it is possible to increase the number of semiconductor material parts 3 and 4 (thermocouples) connected in series included in the thermopile 5. As a result, it is possible to improve the sensitivity of the sensor. Further, according to the present embodiment, it is possible to form the thermopile having the same number of the series of stages in a reduced area. As a result, it is possible to reduce the area of the thin film part in the heat insulating structure, reduce the heat capacity and improve the response speed of the sensor.

Further, according to the present embodiment, the semiconductor material parts 3 and 4 are directly connected. Therefore, in comparison to the infrared ray sensor in the related art (see FIGS. 11A and 11B) in which the thermocouple material parts are connected by the other conductive material parts and the contact parts provided above the thermocouple material parts, it is possible to reduce the thickness of the interlayer dielectric films provided above the cavity part 6. Thus, according to the present embodiment, it is possible to reduce the heat capacity of the sensor in comparison to the infrared ray sensor in the related art and improve the response speed of the sensor.

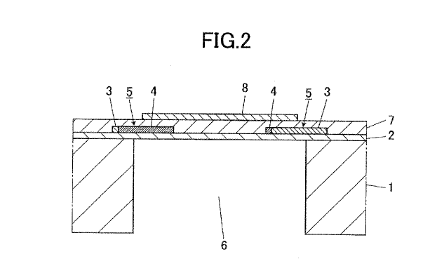

FIG. 2 is a schematic sectional view illustrating another embodiment. The plan view thereof is the same as that of FIG. 1A. In FIG. 2, the same reference numerals are given to parts having the same functions as those shown in FIGS. 1A and 1B.

In the embodiment shown in FIGS. 1A and 1B, the cavity part 6 has a tapered shape (see FIG. 1B). However, according to the present embodiment of FIG. 2, the cavity part 6 is formed vertically with respect to the bottom surface of the substrate 1 without having a tapered shape. The shape of cavity part 6 shown in FIG. 2 can be formed by anisotropic dry etching. The shape of the cavity part 6 shown in FIG. 1B can be formed by wet etching carried out to a single crystal silicon using an alkaline solution. Note that the shape of the cavity part 6 can be any shape.

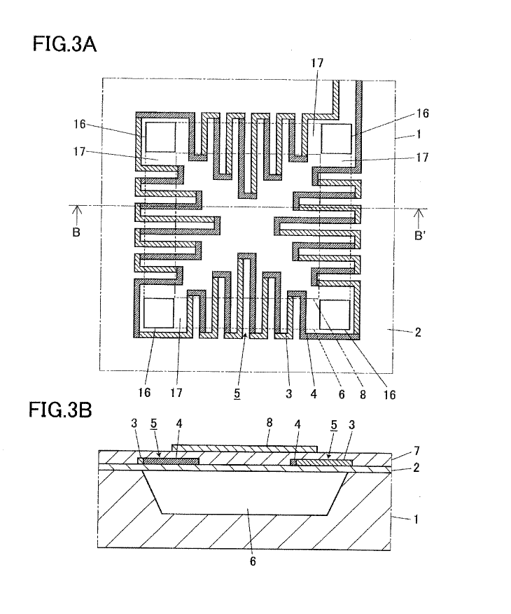

FIGS. 3A and 3B are schematic views illustrating yet another embodiment. FIG. 3A is a plan view and FIG. 35 is a sectional view taken along a B-B′ line of FIG. 3A. In FIGS. 3A and 3B, the same reference numerals are given to parts having the same functions as those shown in FIGS. 1A and 1B.

The present embodiment of FIGS. 3A and 3B is different in the heat insulating structure in comparison to the embodiment shown in FIGS. 1A and 1B. The heat insulating structure in the present embodiment has four beam parts 17 sandwiched by four opening parts 16 formed to pass through the interlayer dielectric films 7 and the dielectric film 2. The four beam parts 17 support the thin film part in which the hot junctions in the thermopile 5 are formed. The other parts are the same as those of FIGS. 1A and 1B and duplicate description will be omitted.

By providing such a beam shape, the heat insulation is improved and the sensitivity in the sensor can be improved. The shape shown in FIGS. 3A and 3B is one example. Other than the shape of FIGS. 3A and 3B, it is possible to change the shapes and the number of the beam parts 17 by changing the shapes and the number of the opening parts 16. Thus, an embodiment of the present invention is not limited to the above-mentioned shape.

In the structure shown in FIGS. 3A and 3B, the cavity part 6 can be formed through the opening parts 16 using a wet etching process with an alkali etchant such as KOH, TMAH or the like. Note that also in the structures shown in FIGS. 1A and 1B and FIG. 2, it is possible to form beam parts by providing opening parts that pass through the interlayer dielectric films 7 and the dielectric film 2.

Note that in the above-mentioned embodiment of FIGS. 3A and 3B, the first semiconductor material parts 3 and the second semiconductor material parts 4 are formed in the same semiconductor layer. Further, in order to realize the high impurity concentration of the semiconductor material parts on the order of 10²⁰ cm⁻³, mentioned above as an example, a long period of time is required when using ion implantation and throughput may be degraded. However, it is also possible to form the first semiconductor material parts 3 and the second semiconductor material parts 4 in the same semiconductor layer using photoengraving and ion implantation.

In order to realize high impurity concentrations in the semiconductor material parts, there is a case where using a surface diffusion method to introduce impurity is rather advantageous. In this case, impurity diffuses also laterally. Therefore, in order to separately form the first semiconductor material parts 3 and the second semiconductor material parts 4 in the same semiconductor layer using a surface diffusion method, it is necessary to provide some distances between the first semiconductor material parts 3 and the second semiconductor material parts 4. Thereby, the required area for the thermopile 5 increases.

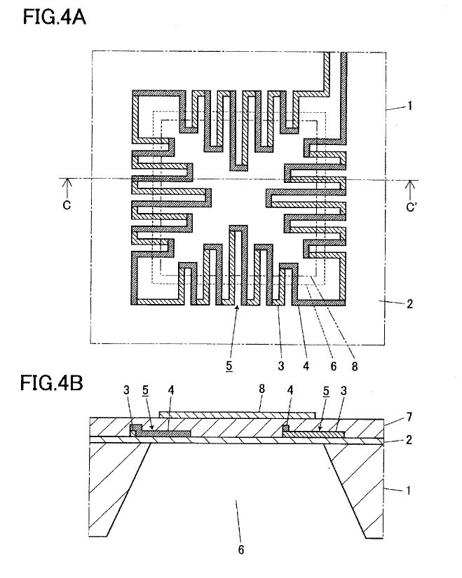

In contrast thereto, by forming the first semiconductor material parts 3 and the second semiconductor material parts 4 using mutually different layers of semiconductor materials, it is possible to reduce the required spaces between the first semiconductor material parts 3 and the second semiconductor material parts 4 even using a surface diffusion method for forming the first semiconductor material parts 3 or the second semiconductor material parts 4. Using FIGS. 4A and 4B, an embodiment will be described in which the first semiconductor material parts 3 and the second semiconductor material parts 4 are formed by using mutually different layers of semiconductor materials.

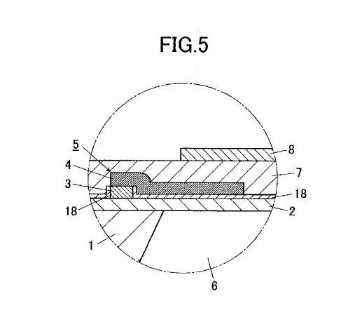

FIGS. 4A and 4B are schematic views illustrating yet another embodiment. FIG. 4A is a plan view and FIG. 4B is a sectional view taken along a C-C′ line of FIG. 4A. FIG. 5 is a schematic sectional view showing a connection part between semiconductor material parts in the embodiment of FIGS. 4A and 4B in a magnified manner. In FIGS. 4A and 4B and FIG. 5, the same reference numerals are given to parts having the same functions as those shown in FIGS. 1A and 1B.

First semiconductor material parts 3 and second semiconductor material parts 4 are formed by using mutually different layers of semiconductor materials. In hot junctions and cold junctions in a thermopile 5, the second semiconductor material parts 4 in an upper layer are placed over the first semiconductor material parts 3 in a lower layer. According to the present embodiment, only the connection parts of the semiconductor material parts 3 and 4 overlap each other. However, positions at which the semiconductor material parts 3 and 4 overlap each other are not limited thereto in an embodiment of the present invention.

As shown in FIG. 5, the surface of the first semiconductor material part 3 is covered by the dielectric film 18 except for the connection part connected with the second semiconductor material part 4. The first semiconductor material part 3 and the second semiconductor material part 4 are electrically connected with one another via an opening formed in the dielectric film 18.

A specific method of forming the configuration is such that, first, a semiconductor layer for forming the first semiconductor material part 3 in a lower layer is formed. Then, the thus formed semiconductor layer is patterned and the first semiconductor material part 3 is formed. Further, thereon, the second semiconductor material part 4 in an upper layer is formed. The dielectric film 18 is, for example, a silicon oxide film such as BPSG, NSG, TEOS or the like formed by plasma CVD or the like. An actual thickness of the dielectric film 18 is not limited in an embodiment of the present invention. Further, the dielectric film 18 can be a laminated film made from a plurality of layers being laminated.

Further, when the first semiconductor material parts 3 in the lower layer is made of polysilicon, amorphous silicon or single crystal silicon, the dielectric film 18 can be formed by thermally oxidizing the surface of the first semiconductor material parts 3.

Further, when the second semiconductor material parts 4 in the upper layer are formed, first, the dielectric film 18 is removed at the positions of the connection parts between the first semiconductor material parts 3 and the second semiconductor material parts 4. Then, a semiconductor layer for forming the second semiconductor material parts 4 is formed, the thus formed semiconductor layer is patterned and thus the second semiconductor material parts 4 are formed. As a result, it is possible to obtain electrical connection between the first semiconductor material parts 3 and the second semiconductor material parts 4.

Into the first semiconductor material parts 3 or the second semiconductor material parts 4, impurity is introduced through a surface diffusion method. The process of thus introducing impurity in the surface diffusion method can be carried cut before the process of patterning the semiconductor layer or after the process of patterning the semiconductor layer. Further, when the process of introducing impurity is carried out by an ion implantation method, the process can be carried out before the process of patterning the semiconductor layer or after the process of patterning the semiconductor layer. Further, it is also possible to carry out the process of introducing impurity at the same time of forming the semiconductor layer.

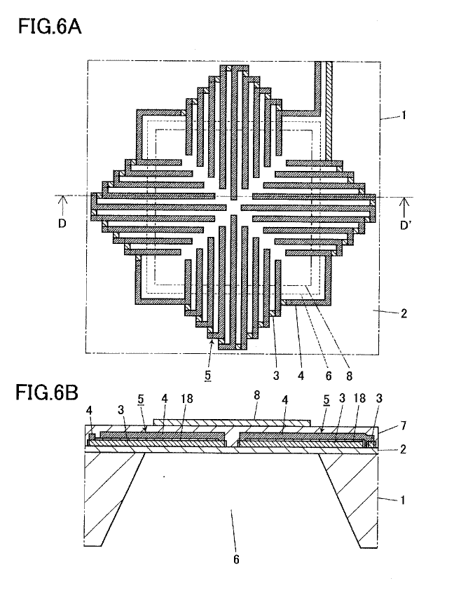

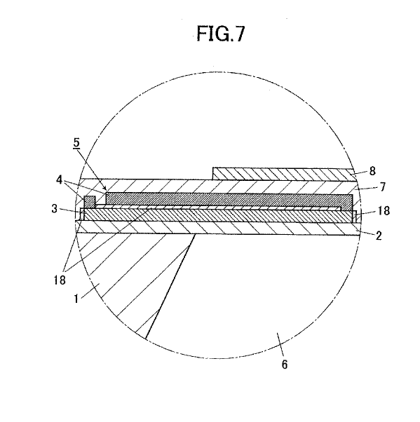

FIGS. 6A and 6B are schematic views illustrating yet another embodiment. FIG. 6A is a plan view and FIG. 6B is a sectional view taken along a D-D′ line of FIG. 6A. FIG. 7 is a schematic sectional view showing a connection part between semiconductor material parts in the embodiment of FIGS. 6A and 6B. In FIGS. 6A and 6B and FIG. 7, the same reference numerals are given to parts having the same functions as those shown in FIGS. 4A and 4B and FIG. 5.

According to the present embodiment of FIGS. 6A, 6B and 7, the number of the series of stages of semiconductor material parts 3 and 4 of thermocouples in a thermopile 5 is further increased. According to the present embodiment, in almost all of the area, the first semiconductor material parts 3 and the second semiconductor material parts 4 are laminated together. Thereby, it is possible to obtain the number of the series of stages approximately double in comparison to the embodiment of FIGS. 4A, 4B and 5. Thus, it is possible to improve the sensitivity of the sensor.

The first semiconductor material parts 3 are covered by the dielectric films 18. At the connection parts between the first semiconductor material parts 3 and the second semiconductor material parts 4, the dielectric films 18 are removed.

FIGS. 8A, 8B, 8C, 8D and 8E are schematic sectional views illustrating an example of processes of manufacturing the thermopile 5 according to the embodiment of FIGS. 6A, 6B and 7.

First, a semiconductor layer for forming a semiconductor material part 3 is formed on a dielectric film 2 formed on a substrate 1. The semiconductor layer is, for example, made of polysilicon. The semiconductor layer is patterned and the first semiconductor material part 3 is formed as shown in FIG. 8A. A process of introducing impurity into the first semiconductor material part 3 can be carried out before the semiconductor layer is patterned or after the semiconductor layer is patterned.

Then, as shown in FIG. 8B, a dielectric film 18 is formed on the surface of the first semiconductor material part 3. The dielectric film 18 is, for example, a silicon oxide film obtained from thermally oxidizing the surface of the first semiconductor material part 3. However, in an embodiment of the present invention, the dielectric film 18 is not limited thereto and can be a silicon oxide film made of BPSG, NSG, TEOS or the like formed by plasma CVD or the like. In this case, the dielectric film 18 is formed also on the dielectric film 2. Further, the dielectric film 18 can be another type of a dielectric film or can be a laminated film obtained from laminating a plurality of films.

Then, as shown in FIG. 8C, the dielectric film 18 is removed at positions where the semiconductor material parts 3 and 4 are mutually connected (to be connection parts therebetween).

Then, as shown in FIG. 8D, a semiconductor layer 4a for forming the second semiconductor material part 4 is formed. The semiconductor layer 4a is, for example, made of polysilicon.

Then, as shown in FIG. 6E, the semiconductor layer 4a is patterned and the second semiconductor material part 4 is formed. Thereby, a thermopile 5 is formed. A process of introducing impurity into the second semiconductor material part 4 can be carried out before the semiconductor layer 4a is patterned or after the semiconductor layer 4a is patterned. Thereafter, interlayer dielectric films 7 and an infrared absorbing film 8 are formed. Then, finally, a cavity part 6 is formed (see FIGS. 6A, 6B and 7). Note that a timing of forming the cavity part 6 is not limited to a timing after the infrared absorbing film 8 is formed and can be any timing in an embodiment of the present invention.

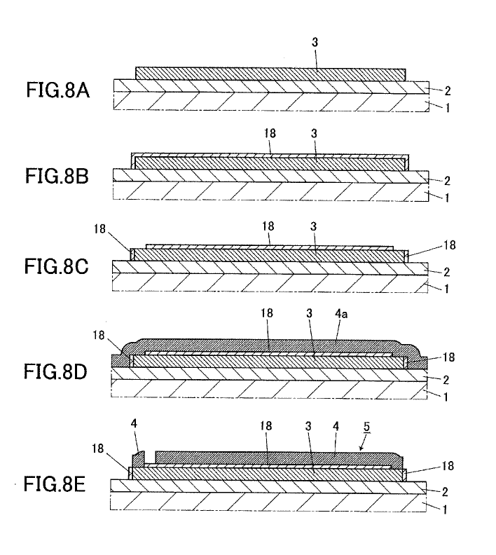

FIG. 9 is a schematic sectional view illustrating yet another embodiment. In FIG. 9, the same reference numerals are given to parts having the same functions as those shown in FIGS. 4A and 4B and FIG. 5.

In the present embodiment of FIG. 9, as shown, a sensor part 19 including thermopiles 5 and a peripheral circuit part 20 are formed in a monolithic manner. Further, the thermopiles 5 including semiconductor material parts 3 and 4 made of polysilicon and a Polysilicon Insulator Polysilicon (PIP) capacitor 22 in the peripheral circuit part 20 are formed simultaneously by a common process.

In the periphery of the sensor part 19, the peripheral circuit part 20 is formed. The peripheral circuit part 20 generally includes a MOSFET part 21 and the PIP capacitor 22, as shown in FIG. 9. The PIP capacitor 22 has a structure of two layers made of polysilicon and is a device usually used in a CMOS process.

Further, the gate electrode in the MOSFET part 21 and the second semiconductor material part 4 are formed by the same semiconductor layer. However, the gate electrode in the MOSFET part 21 can be formed by the same semiconductor layer by which the first semiconductor material part 3 is formed.

According to the embodiment described above using FIGS. 4A, 4B and 5 and the embodiment described above using FIGS. 6A, 6B and 7, in each thermopile 5, the semiconductor material parts 3 and 4 are formed by mutually different layers of polysilicon, and thus, the structure is similar to the PIP capacitor 22. Therefore, when the sensor part 19 and the peripheral circuit part 20 are formed in a monolithic manner, it is possible to form the PIP capacitor 22 and the thermopiles 5 using a common process of polysilicon. As to a detailed process, since the process is the same or similar to the process described above using FIGS. 8A-8E, duplicate explanation will be omitted.

Further, in the peripheral circuit part 20, a plurality of interconnection layers are usually used. Therefore, the thickness of the interlayer dielectric films 7 increases. Therefore, in the sensor part 19, in order to improve the response speed of the sensor, it is preferable to remove unnecessary parts of the interlayer dielectric films 7 by etching so as to reduce the thickness of the thin film part positioned above the cavity part 6.

Further, although an infrared absorbing film 8 can be separately formed, it is also possible to use an interlayer dielectric film(s) 7, a passivation film or the like for substitution. Thereby, it is not necessary to use a special material such as gold black, and thus, it is possible to improve affinity with a usual CMOS process.

FIG. 10 is a schematic plan view illustrating yet another embodiment. In FIG. 10, the same reference numerals are given to parts having the same functions as those shown in FIG. 9.

According to the present embodiment of FIG. 10, sensor parts 19 of thermopile-type infrared ray sensors described above are used as an array sensor. Each sensor part 19 is used as one pixel in an array sensor.

In the present embodiment of FIG. 10, a thin film part surrounded by an opening part 16 is supported by a beam part 17. On the thin film part, a thermopile 5 is formed. A shape and/or an arrangement of the beam part 17 and a shape, an area and/or the like of the thin film part depend on the use of the sensor and/or the specification, and therefore, are not limited to those shown in FIG. 10 in an embodiment of the present invention.

As one example, each thermopile 5 has such a structure that semiconductor material parts 3 and 4 are laminated (see FIG. 7). The outputs of the respective pixels are selected by row selection lines 23 and column selection lines 24, are transmitted to a signal processing circuit (not shown) and are processed.

By using the thermopiles in each of which the semiconductor material parts 3 and 4 are laminated according to the present embodiment, it is possible to form more thermocouples on each beam part 17 having a limited width. Thus, it is possible to Improve the pixel sensitivity of the array sensor.

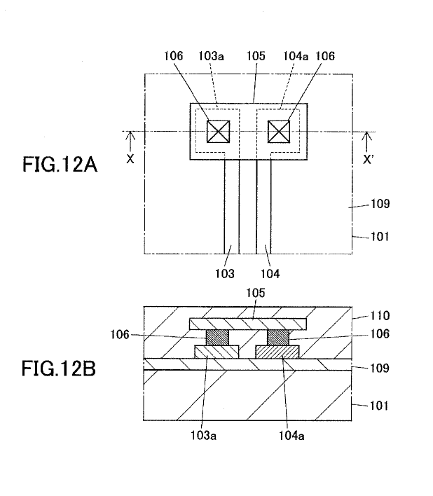

FIGS. 13A, 13B and 13C are schematic views illustrating yet another embodiment. FIG. 13A is a plan view, FIG. 13B is a sectional view taken along an E-E′ line of FIG. 13A and FIG. 13C is a sectional view taken along an F-F′ line of FIG. 13A. In FIGS. 13A-13C, the same reference numerals are given to parts having the same functions as those shown in FIGS. 1A and 1B.

In the embodiment of FIGS. 13A-13C, on a substrate 1, a thermopile 5 is formed that includes first semiconductor material parts 31 and second semiconductor material parts 32 that are laminated. At ends of each pair of the semiconductor material parts 31 and 32, contact holes 33 are formed for obtaining electric connection. Via the contact holes 33 and conductive material parts 34, the first semiconductor material part 31 and the second semiconductor material part 32 included in the thermopile 5 are electrically connected.

The first semiconductor material parts 31 are, for example, made of n-type polysilicon. The second semiconductor material parts 32 are, for example, made of p-type polysilicon. A pair of the first semiconductor material part 31 and the second semiconductor material part 32 are connected and a thermocouple is obtained. A plurality of the thermocouples are connected in series via the contact holes 33 and the conductive material parts 34, and the thermopile 5 is formed.

In the thermopile 5, each pair of the first semiconductor material part 31 and the second semiconductor material part 32 can be made by using materials of different types having Seebeck coefficients with different polarities. For example, it is usual to use a pair of n-type polysilicon and p-type polysilicon that are usually used in a CMOS process. A material usually used in a CMOS process, for example, can be used as a conductive material embedded in the contact holes 33 and the conductive material parts 34 used for interconnections. Specifically, aluminum can be used, for example.

Further, in order to detect weak infrared rays with good sensitivity, a cavity part 6 is formed below the thermopile 5 and a heat insulating structure is formed. Junctions in the thermopile 5 provided on a thin film part thermally insulted by the cavity part 6 function as hot junctions, while junctions in the thermopile 5 provided on a substrate 1 where the cavity part 6 is absent function as cold junctions.

An infrared absorbing film 8 is formed to cover the hot junctions of the thermopile 5. When infrared rays are absorbed by the infrared absorbing film 8 and the thin film part is heated, temperature difference occurs between the hot junctions and the cold junctions, and thus, a thermoelectromotive force is generated in the thermopile 5.

The layer structure in the embodiment of FIGS. 13A-13C is such that, on the dielectric film 2 formed on the substrate 1, the first semiconductor material parts 31, the second semiconductor material parts 32, the contact holes 33, the conductive material parts 34, respective layers of interlayer dielectric films 7 and the infrared absorbing film 8 are arranged.

Specific examples of materials of the respective layers will now be described. As the substrate 1, since a MEMS process of silicon is used for forming the heat insulating structure, a silicon substrate is usually used. The dielectric film 2 is usually made of a thermal oxide film of silicon. The interlayer dielectric films 7 are made of, usually, plasma oxide films or CVD films of silicon. The infrared absorbing film 8 is made of a silicon oxide film, a silicon nitride film, a gold black film or the like.

Below the thermopile 5, the cavity part 6 is formed, and thereby, heat insulation for the hot junctions in the thermopile 5 is improved. In FIGS. 13A-13C, the cavity part 6 having a tapered shape is formed. However, the cavity part 6 can be formed vertically with respect to the substrate 1 without having a tapered shape. Further, although the cavity part 6 passes through the substrate 1 in FIGS. 13B and 13C, an embodiment is not limited thereto as long as a space is formed so that heat insulation is obtained between the hot junctions in the thermopile 5 and the substrate 1 in an embodiment of the present invention.

As shown in FIGS. 13B and 13C, in the thermopile 5 according to the present embodiment, the first semiconductor material part 31 and the second semiconductor material part 32 are laminated.

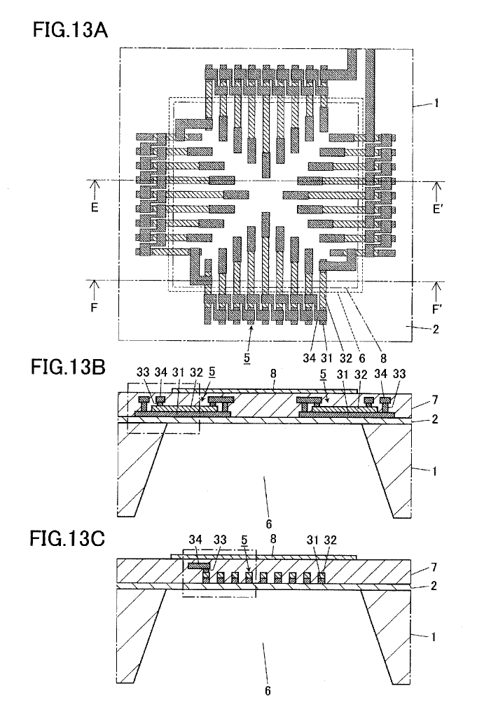

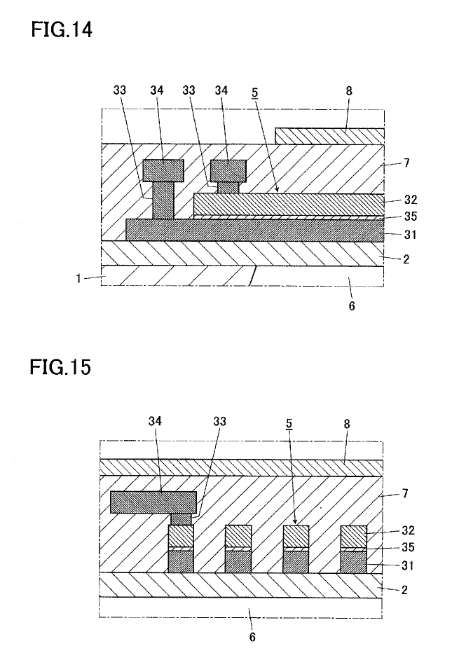

FIG. 14 is a schematic view showing a part enclosed by an alternating long and short dashed line in FIG. 13B in a magnified manner. FIG. 15 is a schematic view showing a part enclosed by an alternating long and short dashed line in FIG. 13C in a magnified manner.

The first semiconductor material part 31 and the second semiconductor material part 32 are formed to have a laminated shape. The first semiconductor material part 31 and the second semiconductor material part 32 are formed in such a manner that, for example, side faces of these parts 31 and 32 along the longitudinal directions of these parts 31 and 32 are patterned simultaneously. Between the first semiconductor material part 31 and the second semiconductor material part 32, an interlayer dielectric film 35 is formed. The interlayer dielectric films 35 is formed to be very thin.

A specific method of forming the interlayer dielectric films 35 is such that, for example, a thermal oxide film of the first semiconductor material part 31 or the like can be used. Alternatively, it is also possible to deposit, on the surface of the first semiconductor material part 31, a plasma oxide film or a CVD oxide film of silicon to form a thin film. Especially, when polysilicon is used as a material of the first semiconductor material part 31, it is advantageous from a viewpoint of forming a thin film and also advantageous from a viewpoint of improving the film quality to use a thermal oxide film of the first semiconductor material part 31 as the interlayer dielectric films 35.

Further, the first semiconductor material part 31 as a lower layer is formed to be longer than the second semiconductor material part 32 as an upper layer. This is for the purpose of forming contact holes 33 for obtaining electric connections at the both ends of the first semiconductor material part 31 and the second semiconductor material part 32, respectively.

Although details of the forming process will be described later, one feature of the infrared ray sensor according to the present embodiment is that side surfaces of the first semiconductor material part 31 and the second semiconductor material part 32 along their longitudinal directions are simultaneously formed by patterning. As a result of these parts 31 and 32 being formed by this process, as shown in FIG. 15, the side surfaces of the first semiconductor material parts 31 and the side surfaces of the second semiconductor material parts 32 along their longitudinal directions are formed on the same planes, respectively.

The infrared ray sensor according to the present embodiment uses the thermocouples in which the first semiconductor material parts 31 and the second semiconductor material parts 32 are laminated. Thereby, it is possible to increase the number of pairs (thermocouples) per unit area in the thermopile 5.

Further, in the infrared ray sensor according to the present embodiment, the thermal oxide film of the first semiconductor material part 31 is provided as the interlayer dielectric film 35 between the first semiconductor material part 31 and the second semiconductor material part 32. Therefore, in comparison to a case of using an interlayer dielectric film other than a thermal oxide film, it is possible to reduce the thickness of the interlayer dielectric film 35. Thereby, it is possible to reduce the heat capacity of the infrared ray sensor according to the present embodiment and it is possible to improve the response characteristics of the sensor.

Further, in the infrared ray sensor according to the present embodiment, the side faces of the first semiconductor material parts 31 and the second semiconductor material parts 32 along their longitudinal directions are formed on the same planes, respectively. Therefore, for example, in comparison to a case where a width of a first semiconductor material part is formed larger than a width of a second semiconductor material part, it is possible to reduce the width of the thermocouple including the first semiconductor material part 31 and the second semiconductor material part 32 according to the present embodiment. As a result, in the infrared ray sensor according to the present embodiment, it is possible to increase the number of pairs (the number of thermocouples) per unit area in the thermopile 5.

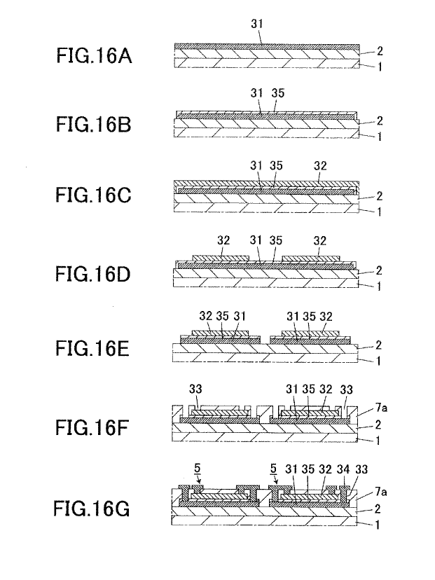

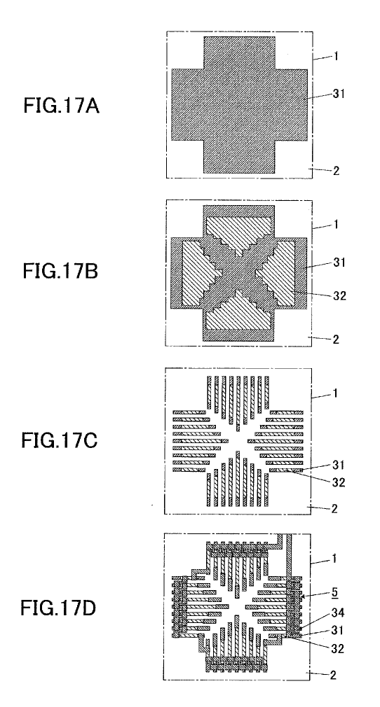

FIGS. 16A, 16B, 16C, 16D, 16E, 16F and 16G are schematic sectional views illustrating one example of processes of manufacturing the thermopile 5 according to the embodiment of FIGS. 13A, 13B and 13C. The sections shown in FIGS. 16A-16G are taken along the line E-E′ in FIG. 13A. FIG. 17A is a schematic plan view corresponding to the schematic sectional view of FIG. 16B. FIG. 17B is a schematic plan view corresponding to the schematic sectional view of FIG. 16D. FIG. 17C is a schematic plan view corresponding to the schematic sectional view of FIG. 16E. FIG. 17D is a schematic plan view corresponding to the schematic sectional view of FIG. 16G.

As shown in FIG. 16A, a first semiconductor material is deposited on a dielectric film 2 formed on a substrate 1. A process of appropriately introducing impurity to the first semiconductor material part 31 is carried out. A specific method of the process of introducing impurity is a method of using, for example, ion implantation, surface diffusion or the like.

As shown in FIGS. 16B and 17A, the first semiconductor material part 31 is patterned in such a manner that approximately an area for finally forming a thermopile 5 is left. This process of patterning includes a series of processes including a process of forming an etching mask made of resist through photolithography using resist; a process of carrying out etching using the thus formed etching mask; and a process of removing the etching mask. Note that the etching mask can be one formed by a method other than photolithography, such as a mask pattern formed by electron beam lithography or an imprint method.

Next, an interlayer dielectric film 35 (omitted in FIGS. 17A-17D) is formed. The interlayer dielectric film 35 is formed by, for example, a thermal oxide film of the first semiconductor material part 31. However, a material of the interlayer dielectric film 35 is not limited thereto in an embodiment of the present invention. For example, an interlayer dielectric film 35 can be formed by depositing a thin plasma oxide film or CVD oxide film of silicon on the first semiconductor material part 31 or on the thermal oxide film of the first semiconductor material part 31. A material of the interlayer dielectric film 35 is not particularly limited as long as the material is such a material and has such a thickness as to be able to electrically insulate the first semiconductor material part 31 and a second semiconductor material part 32 that is formed in a subsequent process. Since a high voltage is not applied to a thermopile 5, it is preferable that a thickness of the interlayer dielectric film 35 is a minimum thickness only for preventing the first semiconductor material part 31 as a lower layer and the second semiconductor material part 32 as an upper layer from being short circuited.

Then, as shown in FIG. 16C, the second semiconductor material part 32 is deposited. A process of appropriately introducing impurity to the second semiconductor material part 32 is carried out. A specific method of the process of introducing impurity is a method of using, for example, ion implantation, surface diffusion or the like.

As shown in FIGS. 16D and 17B, the second semiconductor material part 32 is patterned in such a manner that the approximate areas for finally forming the second semiconductor material parts 32 are left. Note that the sizes of the respective second semiconductor material parts 32 and the positions of the end faces along the longitudinal directions of the respective second semiconductor material parts 32 shown in FIGS. 13A-13C are defined in this patterning process.

Etching is carried out simultaneously on the laminated structure of the first semiconductor material part 31, the interlayer dielectric film 35 and the second semiconductor material parts 32. Thereby, the final shapes of the first semiconductor material parts 31, the interlayer dielectric films 35 and the second semiconductor material parts 32 are formed as shown in FIGS. 16E and 17C.

An interlayer dielectric film 7a is formed to be provided between thermocouples including the first semiconductor material parts 31, the interlayer dielectric films 35 and the second semiconductor material parts 32, and the an interconnection layer that is formed subsequently. Then, contact holes 33 are formed in the thus formed interlayer dielectric film 7a as shown in FIG. 16F. Note that the interlayer dielectric film 7a corresponds to a partial layer of the interlayer dielectric films 7 shown in FIGS. 13B and 13C.

A conductive material is deposited and is patterned to have a desired pattern shape of the conductive material parts 34 as shown in FIGS. 16G and 17D. Thus, a thermopile 5 is formed.

Using FIGS. 13A-13C, processes to be carried out thereafter will now be described. A passivation film for surface protection is formed, forming of the interlayer dielectric films 7 is completed, and thereafter, an infrared absorbing film 8, a cavity part 6 and so forth are formed. Thus, an infrared ray sensor of a thermocouple type is completed.

According to this manufacturing method as one embodiment, a thermopile 5 of a laminated type is formed by using a process of etching first semiconductor material parts 31 and second semiconductor material parts 32 formed in different layers in batch. Assuming a process of patterning first semiconductor material parts and second semiconductor material parts separately, there is a case where a process of planarizing interlayer dielectric films between the first and second semiconductor material parts is required. In contrast thereto, in the above-mentioned manufacturing method according to the embodiment described above using FIGS. 13A-13C, 16A-16G and 17A-17D, such a planarizing process is not needed, and a thermopile 5 of a laminated type is formed that has very thin interlayer dielectric films 35 between the first semiconductor material parts 31 and the second semiconductor material parts 32. Therefore, it is possible to improve the response speed of the sensor according to the manufacturing method of the embodiment.

The above-mentioned manufacturing method according to the embodiment includes the process shown in FIG. 16B of patterning the first semiconductor material part 31 before the process shown in FIG. 16C of forming the second semiconductor material part 32. However, an embodiment of a method of manufacturing an infrared ray sensor according to the present invention is not limited thereto. It is also possible that a process of patterning a first semiconductor material part is not included before forming a second semiconductor material part.

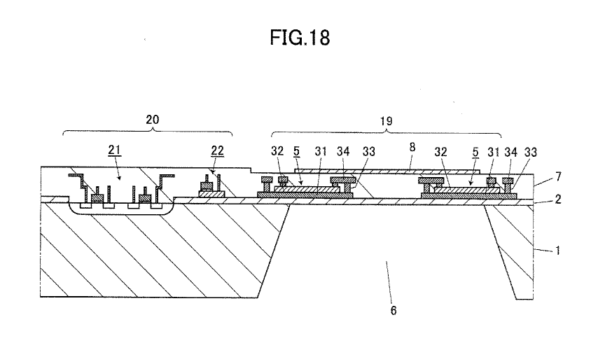

FIG. 18 is a schematic sectional view illustrating yet another embodiment. In FIG. 18, the same reference numerals are given to parts having the same functions as those shown in FIGS. 9 and 13A-13C.

According to the present embodiment of FIG. 18, a sensor part 19 including thermopiles 5 and a peripheral circuit part 20 are formed in a monolithic manner. The peripheral circuit part 20 is formed by, for example, a CMOS process. The peripheral circuit part 20 includes, for example, a MOSFET part 21 and a PIP capacitor 22. The PIP capacitor 22 is a capacitative element in which a lower electrode and an upper electrode are formed by polysilicon.

When the sensor part 19 and the peripheral circuit part 20 are formed in a monolithic manner, it is necessary to simplify the process. That is, it is preferable that the first semiconductor material parts 31 in the thermopile 5 and the lower electrode of the PIP capacitor 22 are formed by common polysilicon. Further, it is preferable that the second semiconductor material parts 32 in the thermopile 5 and the upper electrode of the PIP capacitor 22 are formed by common polysilicon. Further, it is preferable that the first semiconductor material parts 31 or the second semiconductor material parts 32 and a polysilicon gate electrode of the MOSFET part 21 are formed by common polysilicon.

Thus, both of the first semiconductor material parts 31 and the second semiconductor material parts 32 in the infrared ray sensor can be formed by a process that is common with a CMOS process. Therefore, the infrared ray sensor has very high affinity with a CMOS process and it is possible to simplify the process.

Further, the peripheral circuit part 20 is usually formed of a plurality of layers. Thus, the interlayer dielectric films 7 become thicker. Therefore, it is preferable that in the sensor part 19, in order to improve the response speed of the sensor, unnecessary parts of the interlayer dielectric films 7 are removed by etching so that the thickness of the thin film part placed above the cavity part 6 is reduced.

Further, although an infrared absorbing film 8 can be separately formed, it is also possible to substitute an interlayer dielectric film 7, a passivation film or the like for the infrared absorbing film 8. Thereby, it is not possible to use a special material such as gold black or the like, and thus, affinity with a usual CMOS process can be further improved.

According to the embodiment of the infrared ray sensor and the embodiment of the manufacturing method described above using FIGS. 13A-17D, the first semiconductor material parts 31 are made of n-type polysilicon and the second semiconductor material parts 32 are made of p-type polysilicon. However, specific materials of the first semiconductor material parts 31 and the second semiconductor material parts 32 are not limited thereto in an embodiment of the present invention. It is also possible that first semiconductor material parts 31 are made of p-type polysilicon and second semiconductor material parts 32 made of n-type polysilicon.

Further, the first semiconductor material parts 31 and the second semiconductor material parts 32 can be ones into which impurities that generate carriers of the same polarity are introduced with mutually different concentrations, and also, the polarities of Seebeck coefficients thereof can be the reverse of one another. The first semiconductor material parts 31 and the second semiconductor material parts 32 can be formed by the same materials as those of the semiconductor material parts 3 and 4 in the embodiment described above using FIGS. 1A and 1B.

Further, the infrared ray sensor according to the embodiment described above using FIGS. 13A-13C and so forth can be applied to a configuration in which a plurality of thermopiles 5 are placed to form an array the same as or similar to the embodiment described above using FIG. 10, for example.

Thus, the embodiments of the present invention have been described. However, the specific numerical values, materials arrangements, numbers and so forth are examples, embodiments of the present invention are not limited thereto, and variations and modifications may be made without departing from the scope of the present invention.

For example, in thermocouples and infrared ray sensors according to embodiments of the present invention, base materials of first semiconductor material parts and second semiconductor material parts are not limited to polysilicon. It is preferable that first semiconductor material parts and second semiconductor material parts are ones into which impurities that generate carriers of the same polarity are introduced with mutually different concentrations, and also, polarities of Seebeck coefficients thereof are the reverse of one another. For example, basic materials of the first semiconductor material part and the second semiconductor material parts can be semiconductor materials other than silicon-based semiconductor materials such as single crystal silicon, amorphous silicon and so forth.

Further, in the above-mentioned embodiments, the thermocouples are applied to the thermopiles. However, thermocouples according to embodiments of the present invention are not limited thereto, and can be used for purposes other than thermopiles.

Further, in the above-mentioned embodiments, the thermocouples are connected in series in the thermopiles. However, thermopiles according to embodiments of the present invention are not limited thereto, and can be those in which a plurality of thermocouples are connected in parallel.

Further, in the above-mentioned embodiments, the infrared ray sensors have the cavity parts. However, infrared ray sensors according to embodiments of the present invention are not limited thereto, and an infrared ray sensor according to an embodiment of the present invention can be one in which a thermopile is provided in which a plurality of thermocouples are connected in series.

Thus, the thermocouples, thermopiles and inferred ray sensors have been described in the embodiment. However, the present invention is not limited to the specifically disclosed embodiment and variations and modifications may be made without departing from the scope of the present invention.

The present application is based on and claims the benefit of priority of Japanese Priority Application No. 2013-192685, dated Sep. 18, 2013, the entire contents of which are hereby incorporated herein by reference.

What is claimed is:

1. An infrared ray sensor comprising:
a thermopile, wherein
the thermopile includes a first semiconductor material part and a second semiconductor material part,
the first semiconductor material part and the second semiconductor material part are laminated, and
a dielectric film is provided between the first semiconductor material part and the second semiconductor material part.

2. The infrared ray sensor as claimed in claim 1, wherein
the dielectric film is a thermal oxide film of the first semiconductor material part.

3. The infrared ray sensor as claimed in claim 2, further comprising:
another dielectric film laminated on the thermal oxide film between the first semiconductor material part and the second semiconductor material part.

4. The infrared ray sensor as claimed in claim 1, wherein
the first semiconductor material part and the second semiconductor material part have impurities introduced thereinto with concentrations that are different between the first semiconductor material part and the second semiconductor material part, the impurities generating carriers with polarities that are the same between the first semiconductor material part and the second semiconductor material part, and the first semiconductor material part and the second semiconductor material part have Seebeck coefficients with polarities that are reversed between the first semiconductor material part and the second semiconductor material part.

5. The infrared ray sensor as claimed in claim 4, wherein
The concentrations of the impurities introduced into the first semiconductor material part and the second semiconductor material part are selected or adjusted in such a manner that the polarities of the Seebeck coefficients are reversed between the first semiconductor material part and the second semiconductor material part.

6. The infrared ray sensor as claimed in claim 4, wherein
the first semiconductor material part and the second semiconductor material part are made of semiconductor materials that chiefly include silicon.

7. The infrared ray sensor as claimed in claim 4, wherein
the impurities introduced into the first semiconductor material part and the second semiconductor material part are n-type impurities.

8. The infrared ray sensor as claimed in claim 4, wherein
in either one of the first semiconductor material part and the second semiconductor material part, the concentration of the impurity reaches a solid-solubility limit.

9. The infrared ray sensor as claimed in claim 1, wherein
side faces of the first semiconductor material part and the second semiconductor material part lying along longitudinal directions of the first semiconductor material part and the second semiconductor material part lie on a same plane.

10. A method of manufacturing the infrared ray sensor claimed in claim 1, the method comprising:
etching the first semiconductor material part and the second semiconductor material part simultaneously.

11. A thermocouple comprising:
a first semiconductor material part and a second semiconductor material part that are electrically connected, wherein
the first semiconductor material part and the second semiconductor material part have impurities introduced thereinto with concentrations that are different between the first semiconductor material part and the second semiconductor material part, the impurities generating carriers with polarities that are the same between the first semiconductor material part and the second semiconductor material part, and the first semiconductor material part and the second semiconductor material part have Seebeck coefficients with polarities that are reversed between the first semiconductor material part and the second semiconductor material part.

12. The thermocouple as claimed in claim 11, wherein
the concentrations of the impurities introduced into the first semiconductor material part and the second semiconductor material part are selected or adjusted in such a manner that the polarities of the Seebeck coefficients are reversed between the first semiconductor material part and the second semiconductor material part.

13. The thermocouple as claimed in claim 11, wherein
the first semiconductor material part and the second semiconductor material part are made of semiconductor materials that chiefly include silicon.

14. The thermocouple as claimed in claim 11, wherein
the impurities introduced into the first semiconductor material part and the second semiconductor material part are n-type impurities.

15. The thermocouple as claimed in claim 11, wherein
in either one of the first semiconductor material part and the second semiconductor material part, the concentration of the impurity reaches a solid-solubility limit.

16. The thermocouple as claimed in claim 11, wherein
the first semiconductor material part and the second semiconductor material part are formed by different layers of semiconductor materials, respectively.

17. A thermopile comprising:
a plurality of the thermocouples claimed in claim 11 connected in series or parallel with each other.

18. An infrared ray sensor comprising:
the thermopile claimed in claim 17, wherein
the plurality of the thermocouples are connected in series with each other.

19. The infrared ray sensor as claimed in claim 1, wherein
the thermopile and a peripheral circuit are formed on the same substrate.

20. The infrared ray sensor as claimed in claim 1, wherein
a plurality of the thermopiles are arranged to form an array.
